(19) United States
(12) Patent Application Publication
(10) Pub. No.: US 2026/0314430 A1
(43) Pub. Date: Oct. 8, 2026

(54) METHOD OF MANUFACTURING SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/277,404

(22) Filed: Jul. 23, 2025

(30) Foreign Application Priority Data
Apr. 3, 2025 (KR) 10-2025-0043546

(51) Int. Cl. H10W 46/00; H10W 70/05; H10W 70/65; H10W 70/652

(52) U.S. Cl. CPC H10W 46/00; H10W 46/301; H10W 46/503; H10W 70/05; H10W 70/65; H10W 70/652

(57) ABSTRACT

A method of manufacturing a semiconductor device may include preparing a substrate including a chip region in which a wiring layer is disposed and a scribe lane region in which an alignment pattern layer is disposed; forming an insulating structure that covers the wiring layer and the alignment pattern layer; etching the insulating structure so that the upper surface of the alignment pattern layer is entirely exposed; depositing a redistribution material on the alignment pattern layer and the insulating structure; and etching the redistribution material by aligning an etch mask with a region that is located between the alignment pattern layer and a neighboring alignment pattern layer and is at least partially surrounded by the redistribution material.

### CROSS-REFERENCE TO RELATED APPLICATION

The present application claims priority under 35 U.S.C. §119(a) to Korean Patent Application No. 10-2025-0043546 filed on April 3, 2025, which is incorporated herein by reference in its entirety.

### BACKGROUND

1. Technical Field

Embodiments of the present disclosure relate generally to a method of manufacturing a semiconductor device.

2. Related Art

Semiconductor devices are attracting attention as an important element in the electronics industry due to their characteristics such as miniaturization, multi-functionality and/or low manufacturing cost. As the electronics industry advances, semiconductor devices are increasingly required to be highly integrated.

In order to meet the requirements for high integration, semiconductor devices may include redistribution patterns. The redistribution patterns may be electrically connected to chip pads, and may extend from a region where the chip pads are disposed to another region.

### SUMMARY

Advantages of embodiments of the disclosure are not limited to those set forth herein, and other unmentioned advantages would be apparent to one of ordinary skill in the art from the following description.

Embodiments of the present disclosure are directed to providing a method of manufacturing a semiconductor device capable of preventing deterioration of device characteristics due to process defects.

In an embodiment of the present disclosure, a method of manufacturing a semiconductor device may include preparing a substrate that includes a chip region in which a wiring layer is disposed and a scribe lane region in which an alignment pattern layer is disposed; forming an insulating structure that covers the wiring layer and the alignment pattern layer; etching the insulating structure so that the upper surface of the alignment pattern layer is entirely exposed; depositing a redistribution material on the alignment pattern layer and the insulating structure; and etching the redistribution material by aligning an etch mask with a region that is located between the alignment pattern layer and a neighboring alignment pattern layer and is at least partially surrounded by the redistribution material.

In an embodiment of the present disclosure, a method of manufacturing a semiconductor device may include preparing a substrate that includes a chip region in which a wiring layer is disposed and a scribe lane region in which an alignment pattern layer is disposed; forming an insulating structure that covers the wiring layer and the alignment pattern layer; etching the insulating structure to expose at least a part of the upper surface of the wiring layer; depositing a redistribution material on the alignment pattern layer and the insulating structure; etching the redistribution material by aligning an etch mask with a region that is located between the alignment pattern layer and a neighboring alignment pattern layer and is at least partially surrounded by the redistribution material; and forming a redistribution pattern layer on the wiring layer.

In an embodiment of the present disclosure, a method of manufacturing a semiconductor device may include forming a wiring layer in a first region of a substrate and an alignment pattern layer in a second region of the substrate; covering the wiring layer and the alignment layer with an insulating structure; etching the insulating structure to expose the alignment pattern layer; forming a redistribution material on the exposed alignment pattern layer and a remaining insulating structure; and etching the redistribution material to expose a side surface of the alignment pattern layer.

The advantages of the embodiments of the present disclosure are not limited to the foregoing advantages, and other advantages will be apparent to one of ordinary skill in the art from the following detailed description.

According to embodiments of the present disclosure, it is possible to provide a method of manufacturing a semiconductor device capable of preventing deterioration of device characteristics due to process defects.

### BRIEF DESCRIPTION OF THE DRAWINGS

The embodiments of the present disclosure will be more fully understood from the following detailed description and the accompanying drawings, which are provided for illustration only and are not intended to limit the embodiments.

FIG. 1 is a view illustrating a wafer in which semiconductor devices are integrated according to embodiments of the present disclosure.

FIG. 2 is an enlarged view of a region A of FIG. 1.

FIG. 3 is a flowchart of a method of manufacturing a semiconductor device according to an embodiment of the present disclosure.

FIG. 4 to FIG. 10 are cross-sectional views taken along a line I-I’ of FIG. 2 or a cross-sectional view taken along a line II-II’ of FIG. 2, illustrating the method of manufacturing a semiconductor device according to an embodiment of the present disclosure.

FIG. 11 and FIG. 12 are plan views of a redistribution alignment key region AR of FIG. 2, illustrating the method of manufacturing a semiconductor device according to an embodiment of the present disclosure.

### DETAILED DESCRIPTION

Hereinafter, embodiments of the present disclosure will be described in detail with reference to the accompanying drawings. In the following description, the same elements will be designated by the same reference numerals although they are shown in different drawings. Further, in the following description of the present disclosure, a detailed description of known functions and configurations incorporated herein will be omitted when it may make the subject matter of the present disclosure rather unclear. Terms such as “including” and “comprising” used herein are generally intended to allow other components to be added unless the terms are used with the term “only”. Any references to singular may include plural unless expressly stated otherwise.

Also, in describing the components of the embodiments, there may be terms used like first, second, A, B, (a), and (b). These are solely for the purpose of differentiating one component from another component but do not limit the substances, order, sequence or number of the components.

In a description of the positional relationship of components, when it is described that two or more components are "connected", it should be understood that the two or more components may be directly "connected" but may also be "connected" with another component other than the two or more components additionally "interposed" therebetween. Here, the other component may be included in one or more of the two or more components that are "connected" to each other.

In the description of the temporal flow relationship related to components, operation methods or manufacturing methods, when the temporal chronological relationship or the chronological flow relationship is described, for example, by "after," "before," etc., non-continuous cases may be included unless the term “directly” or “immediately” is used together.

In the case where a numerical value for a component or its corresponding information (e.g., a level, etc.) is mentioned, even though there is no separate explicit description, the numerical value or its corresponding information can be interpreted as including an error range that may be caused by various factors (for example, a process variable, an internal or external shock, noise, etc.).

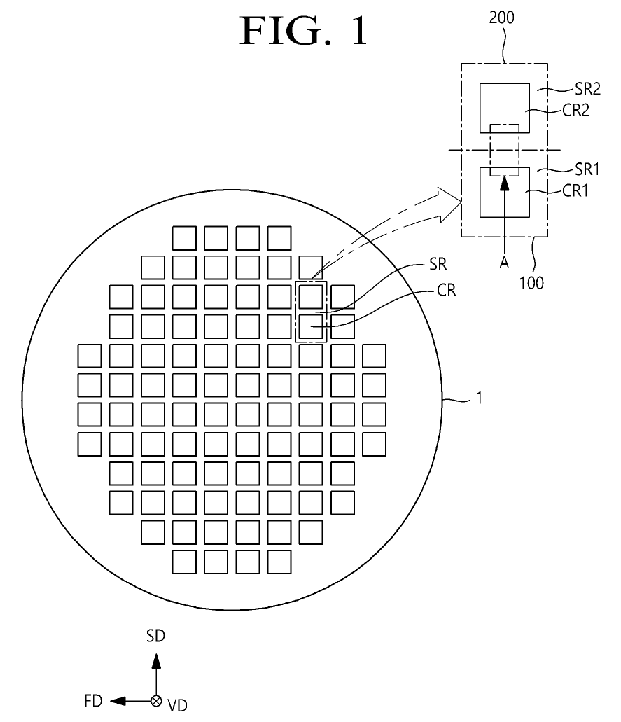

FIG. 1 is a view illustrating a wafer 1 in which semiconductor devices are integrated according to embodiments of the present disclosure.

Referring to FIG. 1, the wafer 1 may include chip regions CR and a scribe lane region SR.

The chip regions CR may comprise semiconductor chips. For example, the chip regions CR may be regions where individual semiconductor chips are formed after the wafer 1 is diced. Integrated circuits for functioning as individual semiconductor chips may exist in the chip regions CR, respectively.

The scribe lane region SR may surround the chip regions CR. The scribe lane region SR may be a continuous region surrounding the chip regions CR. The scribe lane region SR may extend in a first direction FD and a second direction SD to surround the side surfaces of each chip region CR. The first direction FD and the second direction SD may be substantially perpendicular to each other. The scribe lane region SR may be continuous to the chip region CR. In a dicing process, the wafer 1 may be diced along a cutting line in the scribe lane region SR using a laser, a blade, and the like.

Referring to FIG. 1, a first semiconductor device 100 and a second semiconductor device 200 neighboring the first semiconductor device 100 may be included in a partial region of the wafer 1. The region between the first semiconductor device 100 and the second semiconductor device 200 neighboring the first semiconductor device 100 may be defined as a region A.

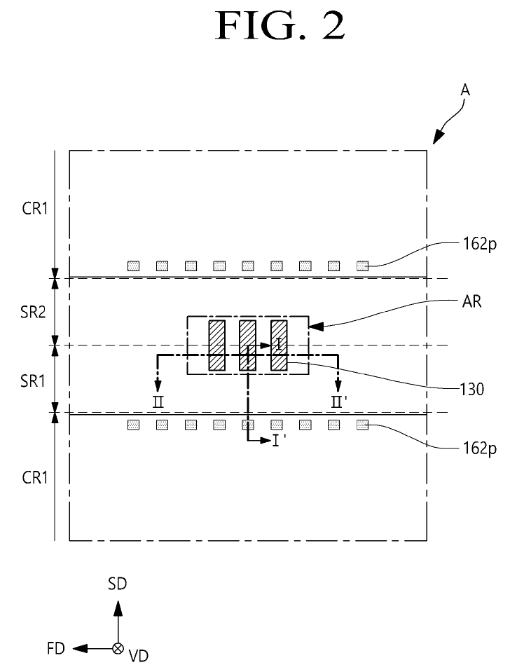

FIG. 2 is an enlarged view of the region A of FIG. 1.

A partial region of the first semiconductor device 100 and a partial region of the second semiconductor device 200 neighboring the first semiconductor device 100 may be included in the region A.

Referring to FIG. 2, a semiconductor device may include a chip region CR and a part of a scribe lane region SR continuous to the chip region CR. Redistribution pad sections 162p may be disposed in the chip region CR.

As illustrated in FIG. 2, a plurality of redistribution pad sections 162p may be spaced apart from each other along a single row that is parallel to the first direction FD. However, this is just an example of the many different possible configurations of the redistribution pad sections 162P. For example, although a limited number of redistribution pad sections 162p are illustrated in FIG. 2, the embodiments of the present disclosure are not limited thereto, and various numbers of redistribution pad sections 162p may be disposed. Also, although FIG. 2 illustrates that the redistribution pad sections 162p are disposed parallel to the first direction FD, the embodiments are not limited thereto. Furthermore, although the redistribution pad sections 162p of FIG. 2 are shown to have a rectangular shape, this is just an example and in other embodiments, or variations of the present embodiment the redistribution pad sections 162p may have an oval, or circle shape. The redistribution pad sections 162p may be electrically connected to chip pads (not illustrated), and may extend from a region where the chip pads are disposed to another region.

A redistribution alignment key region AR may be disposed in a partial region of the scribe lane region SR. The redistribution alignment key region AR may be defined as a region where a redistribution alignment key is disposed. The redistribution alignment key may be used for alignment for etching a redistribution pattern layer in the manufacturing process of a semiconductor device.

The redistribution alignment key region AR may be located between neighboring chip regions CR. The redistribution alignment key region AR may be located centrally in a scribe lane region SR disposed between neighboring chip regions CR. Although FIG. 2 illustrates that the redistribution alignment key region AR is located between chip regions CR neighboring each other in the second direction SD, a location where the redistribution alignment key region AR is disposed is not limited thereto.

An alignment pattern layer 130 may be disposed in the redistribution alignment key region AR. The alignment pattern layer 130 may be a part of a redistribution alignment key. The alignment pattern layer 130 may be used for alignment for etching a redistribution pattern layer in the manufacturing process of a semiconductor device.

Although, in FIG. 2, three alignment pattern layers 130 are illustrated in the redistribution alignment key region AR, the embodiments are not necessarily limited thereto, and the redistribution alignment key region AR may include various numbers of alignment pattern layers 130. The alignment pattern layers 130 may be spaced apart from each other at a regular interval.

Each of the alignment pattern layers 130 may be disposed in a bar shape on a plane defined by the first direction FD and the second direction SD as illustrated in FIG. 2, however, the shape and orientation of the alignment pattern layers is not limited to the configuration illustrated in FIG. 2.

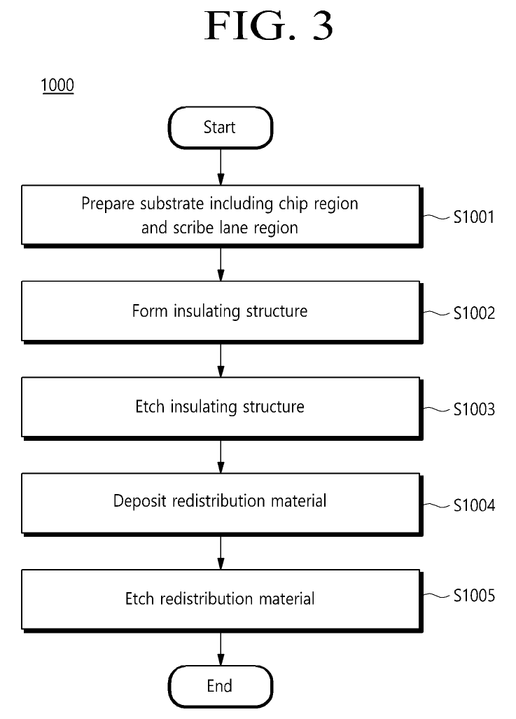

FIG. 3 is a flowchart of a method of manufacturing a semiconductor device according to an embodiment of the present disclosure.

Referring to FIG. 3, a method 1000 of manufacturing a semiconductor device according to an embodiment of the present disclosure may include an operation S1001 of preparing a substrate including a chip region and a scribe lane region, an operation S1002 of forming an insulating structure, an operation S1003 of etching the insulating structure, an operation S1004 of depositing a redistribution material, and an operation S1005 of etching the redistribution material.

Referring to FIG. 3, a substrate including a plurality of chip regions and a scribe lane region as described above with reference to FIG. 1 and FIG. 2 may be prepared (S1001). The chip regions may indicate a first region of a substrate. The scribe lane region may indicate a second region of a substrate. A wiring layer may be disposed in the chip region. An alignment pattern layer may be disposed in the scribe lane region.

An insulating structure may be formed on the substrate (S1002). The insulating structure may be formed to cover the wiring layer. The insulating structure may be formed to also cover the alignment pattern layer.

An operation of etching the insulating structure may be performed (S1003). By etching the insulating structure, the upper surface of the alignment pattern layer may be entirely exposed. The insulating structure may be etched so that the insulating structure exposes at least a part of the upper surface of the wiring layer. The insulating structure may be etched so that the upper surface of the alignment pattern layer is exposed more than the upper surface of the wiring layer.

An operation of depositing a redistribution material may be performed (S1004). The redistribution material may be deposited on the alignment pattern layer. The redistribution material may be deposited on the insulating structure.

An operation of etching the redistribution material may be performed (S1005). By etching the redistribution material, a redistribution pattern layer may be formed on the wiring layer. Before etching the redistribution material, an etch mask may be aligned with a region that is located between the alignment pattern layer and a neighboring alignment pattern layer and is at least partially surrounded by the redistribution material.

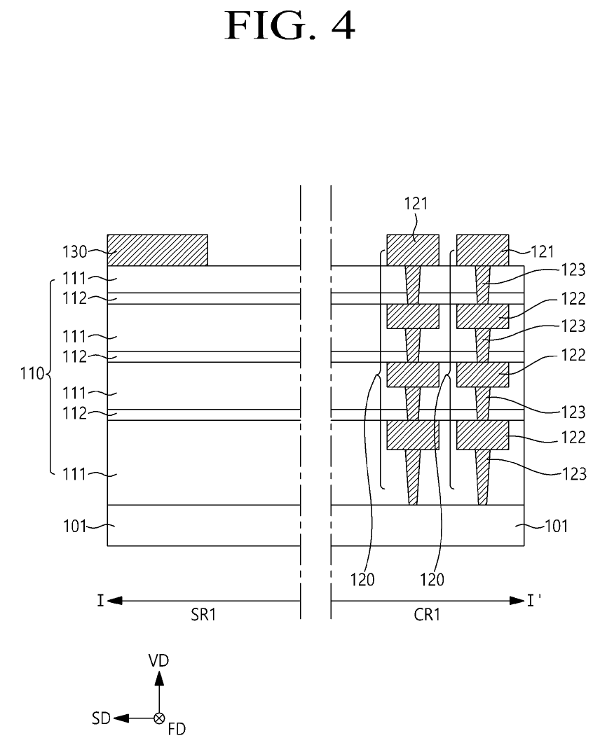

FIG. 4 to FIG. 10 are cross-sectional views taken along a line I-I’ of FIG. 2 or a cross-sectional view taken along a line II-II’ of FIG. 2, illustrating the method of manufacturing a semiconductor device according to an embodiment of the present disclosure.

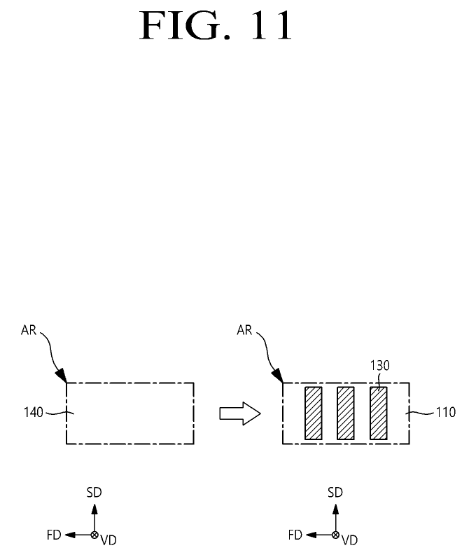

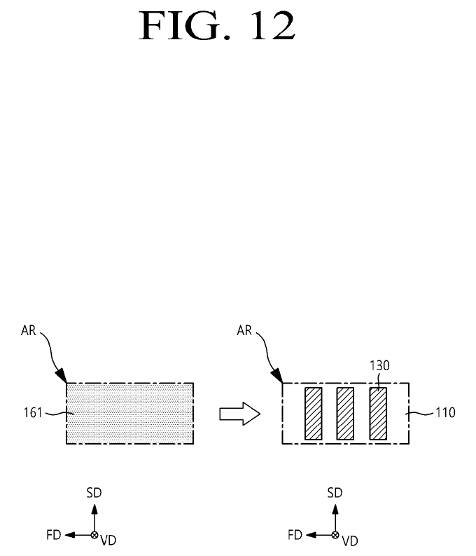

FIG. 11 and FIG. 12 are plan views of the redistribution alignment key region AR of FIG. 2, illustrating the method of manufacturing a semiconductor device according to an embodiment of the present disclosure.

FIG. 4 is a cross-sectional view of a semiconductor device taken along the line Ⅰ-Ⅰ’ of FIG. 2.

Referring to FIG. 4, an interlayer insulating layer 110 may be formed on a substrate 101. A wiring structure 120 may be formed on substrate 101.

The substrate 101 may include a semiconductor substrate such as, for example, a silicon wafer or a silicon-on-insulator (SOI) wafer. The substrate 101 may include a III-V group semiconductor substrate, for example, a compound semiconductor substrate such as gallium arsenide (GaAs). The substrate 101 may include monocrystalline silicon, polysilicon, amorphous silicon, monocrystalline silicon germanium, polycrystalline silicon germanium, carbon-doped silicon, or a combination thereof.

The interlayer insulating layer 110 may include silicon oxide, silicon nitride, silicon oxynitride, low-k dielectric, high-k dielectric, or a combination thereof. The interlayer insulating layer 110 may include an insulating material with excellent step coverage and gapfill characteristics. In an embodiment, the interlayer insulating layer 110 may include an oxide such as tetraethyl orthosilicate (TEOS) or borophosphosilicate glass (BPSG). The interlayer insulating layer 110 may include a first sub interlayer insulating layer 111 and a second sub interlayer insulating layer 112.

One or more wiring structures 120 may be formed in the chip region CR. Each wiring structure 120 may pass through the interlayer insulation layer 110.

The wiring structure 120 may include a wiring layer 121. A plurality of interlayer wiring layers 122 and a plurality of interlayer wiring contacts 123 that connect the plurality of interlayer wiring layers 122 may be formed under the wiring layer 121. The wiring layer 121 may be formed on the interlayer insulating layer 110. In an embodiment, the wiring layer 121 may include aluminum (Al).

An alignment pattern layer 130 may be formed on the interlayer insulating layer 110 in the scribe lane region SR. The interlayer insulating layer 110 may be located between the alignment pattern layer 130 and the substrate 101. The alignment pattern layer 130 may be formed in at least a portion of the scribe lane region SR.

The alignment pattern layer 130 and the wiring layer 121 may be located at the same level or the same layer. The alignment pattern layer 130 may include the same material as the wiring layer 121. In an embodiment, the alignment pattern layer 130 may include aluminum (Al).

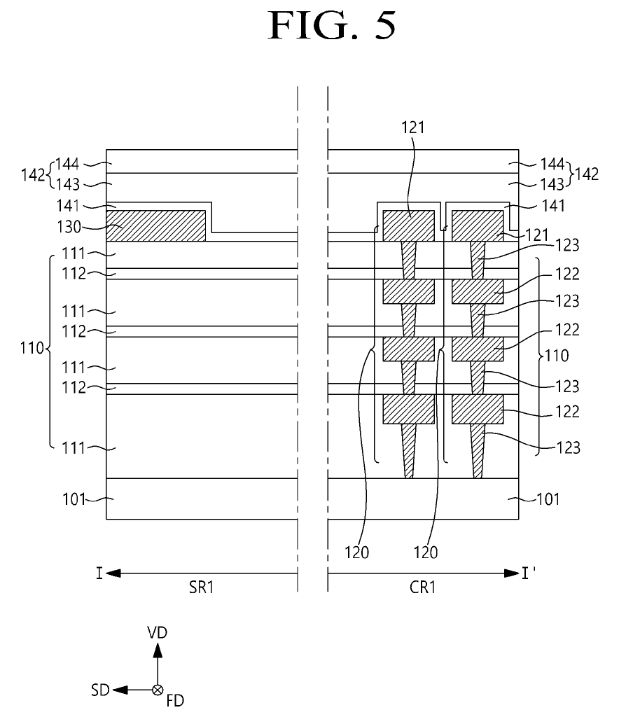

FIG. 5 is a cross-sectional view of the semiconductor device taken along the line Ⅰ-Ⅰ’ of FIG. 2.

Referring to FIG. 5, a protective layer 141 and a passivation layer 142 may be formed sequentially on the interlayer insulating layer 110. The protective layer 141 may be formed to also cover the wiring layer 121 and the alignment pattern layer 130. The protective layer 141 may include, for example, a silicon nitride layer or a silicon oxynitride layer. In an embodiment, the protective layer 141 may be tetraethyl orthosilicate (TEOS).

The passivation layer 142 may include high density plasma oxide, nitride, or a combination thereof. The passivation layer 142 may include a passivation oxide layer 143 and a passivation nitride layer 144. The passivation nitride layer 144 may be located on the passivation oxide layer 143. In an embodiment, the passivation oxide layer 143 may include high density plasma oxide.

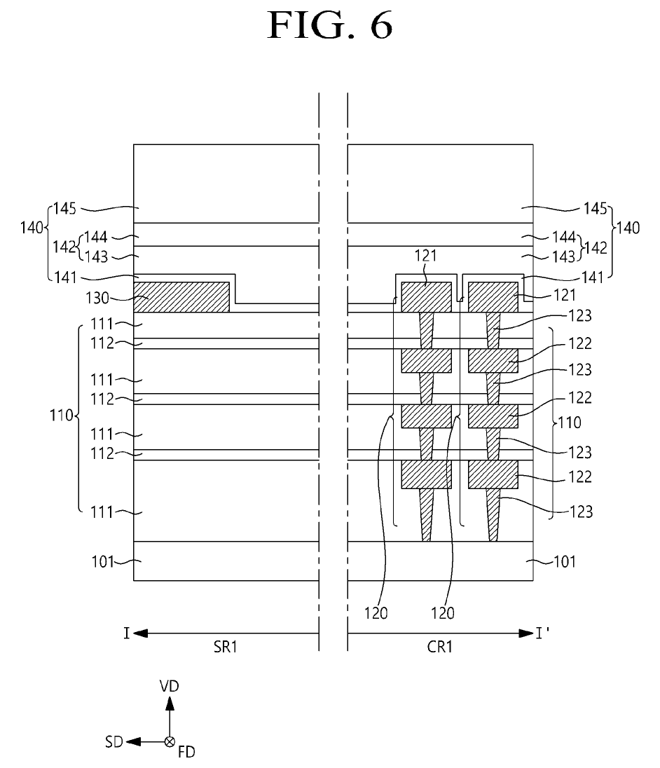

FIG. 6 is a cross-sectional view of the semiconductor device taken along the line Ⅰ-I’ of FIG. 2.

Referring to FIG. 6, a redistribution insulating layer 145 may be formed on the passivation layer 142. The redistribution insulating layer 145 may include silicon oxide, silicon nitride, silicon oxynitride, low-k dielectric, high-k dielectric, or a combination thereof. In an embodiment, the redistribution insulating layer 145 may include an oxide.

An insulating structure 140 (see also FIG. 11) may be defined as including the protective layer 141, the passivation layer 142 and the redistribution insulating layer 145.

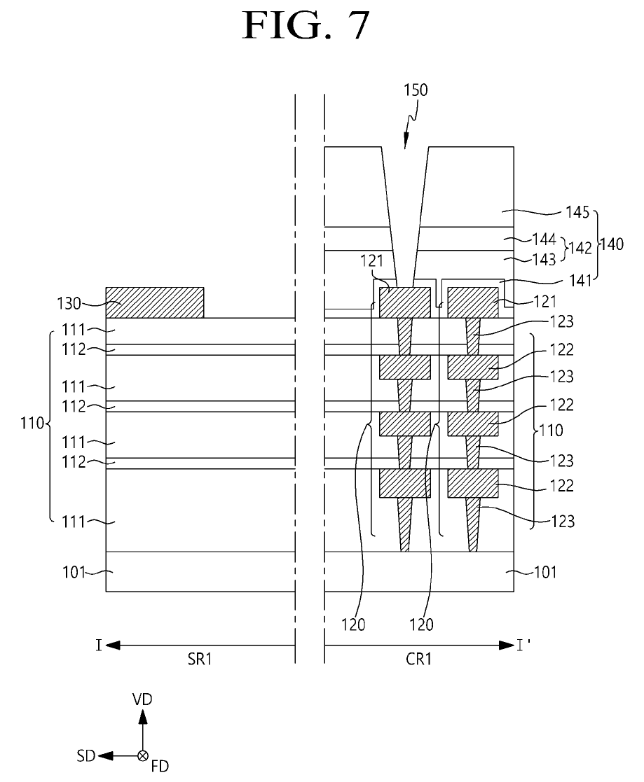

FIG. 7 is a cross-sectional view of the semiconductor device taken along the line Ⅰ-Ⅰ’ of FIG. 2.

Referring to FIG. 7 and FIG. 11, an operation of etching the insulating structure 140 may be performed. Before the operation of etching the insulating structure 140 is performed, an operation of aligning an etch mask (not illustrated) with the alignment pattern layer 130 may be performed. As the insulating structure 140 is etched, the upper surface of the alignment pattern layer 130 may be entirely exposed. As the insulating structure 140 is etched, the side surface of the alignment pattern layer 130 may be exposed. By the operation of etching the insulating structure 140, the upper surface of the interlayer insulating layer 110 that is located between neighboring alignment pattern layers 130 may be exposed.

As the insulating structure 140 is etched, an opening 150 may be formed. The bottom surface of the opening 150 may form the same plane as the upper surface of the alignment pattern layer 130. The opening 150 may extend to expose the upper surface (top surface) of the alignment pattern layer 130. The opening may have a tapered shape with a decreasing cross-sectional area in a direction from the upper surface (top surface) of the redistribution insulating layer 145 toward the upper surface (top surface) of the wiring layer 121.

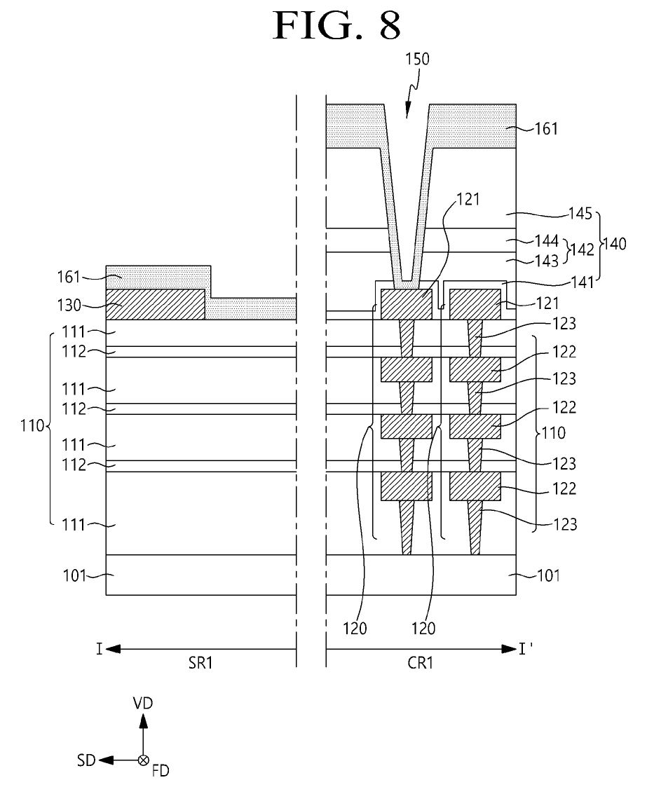

FIG. 8 is a cross-sectional view of the semiconductor device taken along the line Ⅰ-Ⅰ’ of FIG. 2.

Referring to FIG. 8 and FIG. 12, a redistribution material 161 may be deposited to cover the alignment pattern layer 130 in the scribe lane region SR.

The redistribution material 161 may also be deposited to cover the inner side surface of the opening 150 and the upper surface of the insulating structure 140 in the chip region CR. The redistribution material 161 may contact the wiring layer 121 at the bottom of the opening 150.

The redistribution material 161 may include, for example, a conductive metal material such as copper (Cu) or aluminum (Al). In an embodiment, the redistribution material 161 may include aluminum (Al).

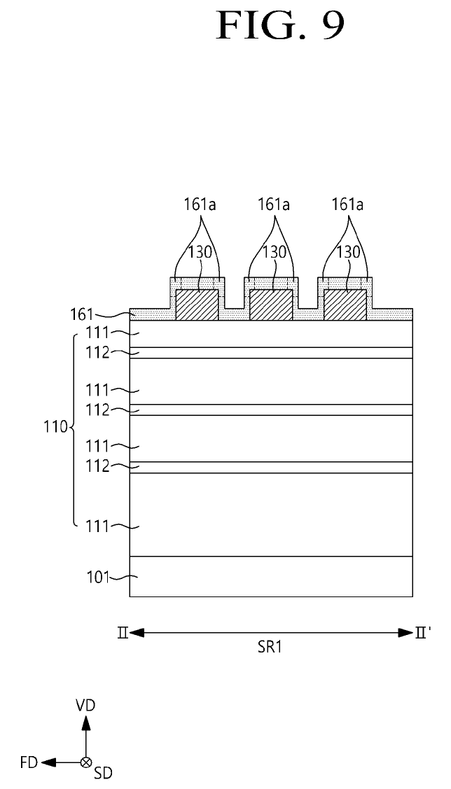

FIG. 9 is a cross-sectional view of the semiconductor device taken along the line ⅠI-ⅠI’ of FIG. 2.

Referring to FIG. 9 and FIG. 2, as the redistribution material 161 is deposited on the alignment pattern layer 130, an overhang 161a may be formed.

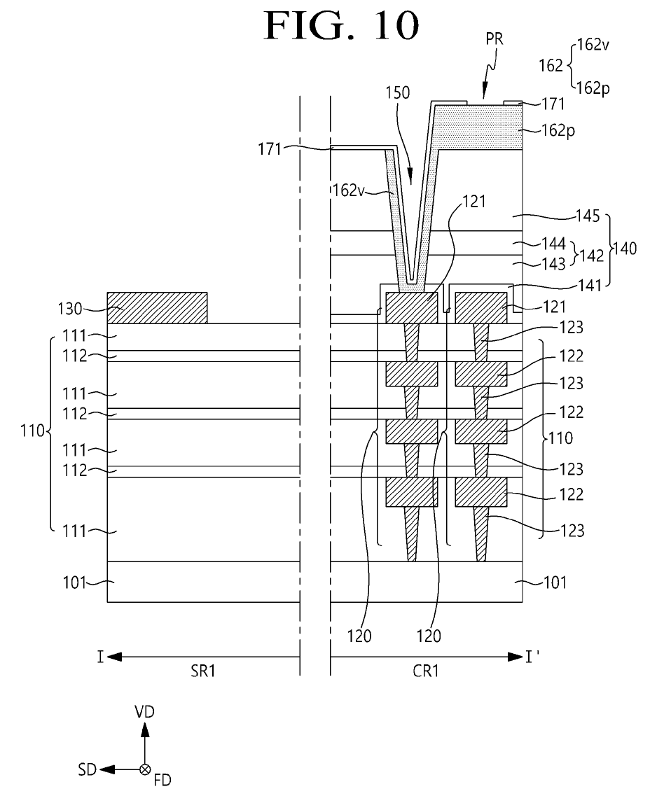

FIG. 10 is a cross-sectional view of the semiconductor device taken along the line Ⅰ-Ⅰ’ of FIG. 2.

Referring to FIG. 10 and FIG. 12, an etching process may be performed on the redistribution material 161. Before the etching process is performed on the redistribution material 161, an operation of aligning an etch mask with a region that is located between an alignment pattern layer 130 and a neighboring alignment pattern layer 130 and is at least partially surrounded by the redistribution material 161 may be performed.

As the redistribution material 161 is etched, the upper surface of the alignment pattern layer 130 may be entirely exposed. As the redistribution material 161 is etched, the side surface of the alignment pattern layer 130 may be exposed. By the operation of etching the redistribution material 161, the upper surface of the interlayer insulating layer 110 that is located between neighboring alignment pattern layers 130 may be exposed.

As the etching process is performed on the redistribution material 161, a redistribution pattern layer 162 may be formed. The redistribution pattern layer 162 may include a redistribution via section 162v and a redistribution pad section 162p. The redistribution pattern layer 162 may be formed in the chip region CR. The redistribution pattern layer 162 may be located on the wiring layer 121. The redistribution via section 162v may be located in the opening 150.

When forming the redistribution pattern layer 162, because the etch mask is aligned with the region between the alignment pattern layer 130 and the neighboring alignment pattern layer 130, an opening may not be formed in the scribe lane region SR. Due to this fact, the cause of poor division may be removed, and cuttability may be improved.

A capping layer 171 may be formed on the redistribution pattern layer 162. In an embodiment, the capping layer 171 may include nitride.

By etching the capping layer 171, a redistribution pad region PR may be opened. The redistribution pad section 162p may be located in the redistribution pad region PR.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. Therefore, the embodiments disclosed above and in the accompanying drawings should be considered in a descriptive sense only and not for limiting the technological scope. The technological scope of the present disclosure is not limited by the embodiments and the accompanying drawings. Furthermore, the embodiments may be combined to form additional embodiments.

What is claimed is:

1. A method of manufacturing a semiconductor device, the method comprising:
preparing a substrate that includes a chip region in which a wiring layer is disposed and a scribe lane region in which an alignment pattern layer is disposed;
forming an insulating structure that covers the wiring layer and the alignment pattern layer;
etching the insulating structure so that an upper surface of the alignment pattern layer is entirely exposed;
depositing a redistribution material on the alignment pattern layer and the insulating structure; and
etching the redistribution material by aligning an etch mask with a region that is located between the alignment pattern layer and a neighboring alignment pattern layer and is at least partially surrounded by the redistribution material.

2. The method according to claim 1, wherein by etching the insulating structure a side surface of the alignment pattern layer is exposed.

3. The method according to claim 2, wherein
an interlayer insulating layer is additionally included between the substrate and the alignment pattern layer, and
by etching the insulating structure an upper surface of the interlayer insulating layer that is located between neighboring alignment pattern layers is exposed.

4. The method according to claim 1, wherein, by etching the insulating structure, an opening is formed on the wiring layer, and
a bottom surface of the opening forms the same plane as the upper surface of the alignment pattern layer.

5. The method according to claim 1, wherein by etching the redistribution material the upper surface of the alignment pattern layer is entirely exposed.

6. The method according to claim 1, wherein by etching the redistribution material a side surface of the alignment pattern layer is exposed.

7. The method according to claim 6, wherein
an interlayer insulating layer is additionally included between the substrate and the alignment pattern layer, and
by etching the redistribution material, the upper surface of the interlayer insulating layer that is located between neighboring alignment pattern layers is exposed.

8. The method according to claim 1, wherein the alignment pattern layer is located at the same layer as the wiring layer.

9. The method according to claim 8, wherein the alignment pattern layer includes the same material as the wiring layer.

10. A method of manufacturing a semiconductor device, the method comprising:
preparing a substrate that includes a chip region in which a wiring layer is disposed and a scribe lane region in which an alignment pattern layer is disposed;
forming an insulating structure that covers the wiring layer and the alignment pattern layer;
etching the insulating structure to expose at least a part of an upper surface of the wiring layer;
depositing a redistribution material on the alignment pattern layer and the insulating structure;
etching the redistribution material by aligning an etch mask with a region that is located between the alignment pattern layer and a neighboring alignment pattern layer and is at least partially surrounded by the redistribution material; and
forming a redistribution pattern layer on the wiring layer.

11. The method according to claim 10, wherein, by etching the insulating structure, a side surface of the alignment pattern layer is exposed.

12. The method according to claim 11, wherein
an interlayer insulating layer is additionally included between the substrate and the alignment pattern layer, and
by etching the insulating structure an upper surface of the interlayer insulating layer that is located between neighboring alignment pattern layers is exposed.

13. The method according to claim 10, wherein an opening is formed on the wiring layer by etching the insulating structure, and
wherein the bottom surface of the opening forms the same plane as the upper surface of the alignment pattern layer.

14. The method according to claim 10, wherein by etching the redistribution material an upper surface of the alignment pattern layer is entirely exposed.

15. The method according to claim 10, wherein by etching the redistribution material a side surface of the alignment pattern layer is exposed.

16. The method according to claim 15, wherein
an interlayer insulating layer is additionally included between the substrate and the alignment pattern layer, and
by etching the redistribution material an upper surface of the interlayer insulating layer that is located between neighboring alignment pattern layers is exposed.

17. The method according to claim 10, wherein the alignment pattern layer is located at a same layer as the wiring layer.

18. The method according to claim 17, wherein the alignment pattern layer includes a same material as the wiring layer.

19. A method of manufacturing a semiconductor device, the method comprising:
forming a wiring layer in a first region of a substrate and an alignment pattern layer in a second region of the substrate;
covering the wiring layer and the alignment pattern layer with an insulating structure;
etching the insulating structure to expose the alignment pattern layer;
forming a redistribution material on the exposed alignment pattern layer and a remaining insulating structure; and
etching the redistribution material to expose a side surface of the alignment pattern layer.

20. The method according to claim 19, wherein by etching the insulating structure so that an upper surface of the alignment pattern layer is exposed more than an upper surface of the wiring layer.
